(19) United States
(12) Patent Application Publication
(10) Pub. No.: US 2026/0206590 A1
(43) Pub. Date: Jul. 16, 2026

(54) CONTINUOUS TRANSIENT COOLING FOR SEMICONDUCTOR CHIP

(71) Applicant: Western Digital Technologies, Inc., San Jose, CA (US)

(72) Inventors: Hussam Zebian, Milpitas, CA (US); Toshiki Hirano, San Jose, CA (US)

(21) Appl. No.: 19/019,098

(22) Filed: Jan. 13, 2025

(51) Int. Cl. H01L 23/473; H01L 23/433

(52) U.S. Cl. CPC H10W 40/47; H10W 40/77

(57) ABSTRACT

Removing heat from a heat-generating device, such as a semiconductor chip, involves a cooling system that includes a thermally conductive solid structure configured for moving over the device, and a liquid metal between the solid structure and the device. Movement of the structure over a heat-emanating surface of the device facilitates transfer of heat generated by the device to the structure via the liquid metal, and physically moves that heat away from the device. Because the solid structure is continuously moving, a continuous cycle of heat transfer, physical movement, and dissipation for cooling the heat-generating device is provided.

### FIELD OF EMBODIMENTS

Embodiments of the invention may relate generally to electronics equipment, and particularly to approaches to cooling semiconductor chips.

### BACKGROUND

It is well-known that electronics, such as those used in data storage and data processing, consume a significant amount of power. Likewise, it is well-known that such power is dissipated in the form of heat, which requires significant cooling and related costs. Recent semiconductor chips (e.g., CPUs (Central Processing Units) and GPUs (Graphics Processing Units)) are consuming more and more power, and the consequent heat generated needs to be removed from the chips by some approach to and/or device for cooling so that the chip temperature remains below its corresponding limit (e.g., typically around 100° Celsius). However, current cooling devices often reach their limits and chips must be “throttled” (i.e., performance reduced) to maintain temperatures below their respective temperature limits. Such throttling results in chip performance degradation.

Any approaches that may be described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

Embodiments are illustrated by way of example, and not by way of limitation, in the figures of the accompanying drawings and in which like reference numerals refer to similar elements and in which:

FIG. 1 is a diagram illustrating an electronics cooling system, according to an embodiment;

FIG. 2 is a diagram illustrating an electronics cooling system with external heat dissipator, according to an embodiment;

FIG. 3A is a diagram illustrating a parallel solid conductive structure for an electronics cooling system, according to an embodiment;

FIG. 3B is a diagram illustrating a perpendicular solid conductive ring structure for an electronics cooling system, according to an embodiment;

FIG. 3C is a diagram illustrating a solid conductive structure at an acute angle for an electronics cooling system, according to an embodiment;

FIG. 4A is a diagram illustrating a parallel translating solid conductive structure for an electronics cooling system, according to an embodiment;

FIG. 4B is a diagram illustrating a perpendicular translating solid conductive structure for an electronics cooling system, according to an embodiment;

FIG. 5A is a diagram illustrating a perpendicular solid conductive structure with heat-conducting appendages for an air-cooled electronics cooling system, according to an embodiment;

FIG. 5B is a diagram illustrating a perpendicular solid conductive structure for a liquid-cooled electronics cooling system, according to an embodiment;

FIG. 6 is a diagram illustrating a parallel solid conductive structure configured for a fluid dynamic bearing for an electronics cooling system, according to an embodiment; and

FIG. 7 is a flow diagram illustrating a method for removing heat from a heat-generating device, according to an embodiment.

### DETAILED DESCRIPTION

Approaches to cooling semiconductor chips are described. In the following description, for the purposes of explanation, numerous specific details are set forth to provide a thorough understanding of the embodiments of the invention described herein. It will be apparent, however, that the embodiments of the invention described herein may be practiced without these specific details. In other instances, well-known structures and devices are shown in block diagram form to avoid unnecessarily obscuring the embodiments of the invention described herein.

### INTRODUCTION

### Terminology

References herein to “an embodiment”, “one embodiment”, and the like are intended to mean that the particular feature, structure, or characteristic being described is included in at least one embodiment of the invention. However, instances of such phrases do not necessarily all refer to the same embodiment.

If used herein, the term “substantially” will be understood to describe a feature that is largely or nearly structured, configured, dimensioned, etc., but with which manufacturing tolerances and the like may in practice result in a situation in which the structure, configuration, dimension, etc. is not always or necessarily precisely as stated. For example, describing a structure as “substantially vertical” would assign that term its plain meaning, such that the structure is vertical for all practical purposes but may not be precisely at 90 degrees throughout.

While terms such as “optimal”, “optimize”, “minimal”, “minimize”, “maximal”, “maximize”, and the like may not have certain values associated therewith, if such terms are used herein the intent is that one of ordinary skill in the art would understand such terms to include affecting a value, parameter, metric, and the like in a beneficial direction consistent with the totality of this disclosure. For example, describing a value of something as “minimal” does not require that the value actually be equal to some theoretical minimum (e.g., zero) but should be understood in a practical sense in that a corresponding goal would be to move the value in a beneficial direction toward a theoretical minimum.

### Context

Semiconductors are the basic materials needed to make integrated circuits and what are commonly referred to as “chips”. A chip is a carrier composed of a semiconductor material on which multiple electronic components are integrated, e.g., transistors, resistors, capacitors, etc. used to perform various circuit functions. Recall that electronics, and high-power semiconductor chips in particular, tend to consume a significant amount of power, and that such power is dissipated in the form of heat. There are several known approaches to high-power chip cooling, such as conduction with forced air cooling, circulating liquid cooling, and evaporation with forced air cooling. To avoid chip throttling and consequent chip performance degradation, higher chip cooling performance may be desired.

### Continuous Transient Heat Removal by Solid-Convection

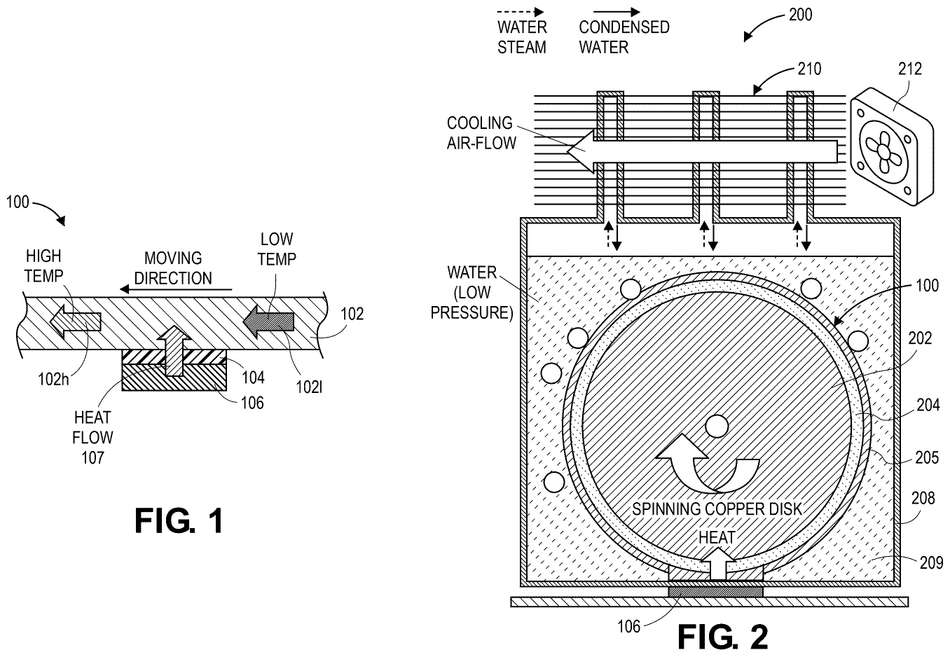

FIG. 1 is a diagram illustrating an electronics cooling system, according to an embodiment. The cooling system 100 of FIG. 1 assists in characterizing an approach to cooling, according to embodiments, in which heat is removed from a heat-generating device whereby the heat is carried away from the device by a moving high-thermal-conductivity solid through a high-thermal-conductivity liquid positioned between the device and the solid. Thus, this approach may be characterized as a “solid-convection” process, whereby heat is transferred by the movement of a solid form of material rather than by movement of a liquid or gas as with the conventional, naturally-occurring form of convection. Regardless of terminology that may be preferred, the approach functions as follows.

Cooling system 100 comprises a highly-thermally conductive solid structure 102 configured to move over a surface of a heat-generating device 106, and a highly-thermally conductive liquid metal 104 (e.g., at least for cooling and for lubrication) positioned between the solid structure 102 and the heat-generating device 106. Consequently, movement of the solid structure 102 over a heat-emanating surface of the heat-generating device 106 facilitates, encourages, promotes the transfer of heat generated by the heat-generating device 106 to the solid structure 102 via the liquid metal 104, and physically moves the heat transferred to the solid structure 102 away from the heat-generating device 106.

For example, a low temperature portion 102l of a substantially continuously moving solid structure 102 (e.g., copper) is moved toward the heat-generating device 106 (e.g., a semiconductor-based chip). In response to the low temperature portion 102l moving in closer proximity to and over the heat-generating device 106, heat generated by the heat-generating device 106 flows/conducts (represented by block arrow 107) from the heat-generating device 106 through the liquid metal 104 (e.g., Indium-Gallium (InGa) alloy) to the solid structure 102, thereby forming/generating a high temperature portion 102h of (e.g., a hot spot on) the moving solid structure 102. In turn, because the solid structure 102 is continuously moving, the high temperature portion 102h is now moving away from the heat-generating device 106 and therefore carries/transports the heat (hot spot) away from the heat-generating device 106. Also, because the solid structure 102 is continuously moving, this is a continuous cycle of heat transfer, physical movement (e.g., dynamic, transient), and dissipation for cooling the heat-generating device 106. Preferably, such a thermodynamic-mechanical cycle should be designed and implemented such that the high temperature portion 102h is cooled down to an appropriate temperature to serve as the low temperature portion 102l according to, for non-limiting examples, a desired cycle-time relative to the amount of heat being removed, a number of passings over the heat-generating device 106, and the like. This may manifest in, for example, a preferred revolutions per second in the context of a revolving solid structure 102. This process is considered especially applicable and beneficial for cooling ultra-high heat flux devices such as some CPUs and GPUs, although implementation is not limited thereto.

While copper may be a preferred material to implement for use as the highly thermally-conductive solid structure 102, the use of other highly thermally-conductive materials such as steel, brass, silver, and the like is also contemplated. Furthermore, while an InGa alloy such as Indium-Gallium-Tin (InGaSn) may be a preferred material to implement for use as the highly thermally-conductive liquid metal 104 (e.g., a thermal interface material, or “TIM”), the use of other highly thermally-conductive liquid thermal interface materials such as mercury and the like is also contemplated. Note that not only does the liquid metal 104 provide a heat-conductive path between the heat-generating device 106 and the solid structure 102 (as a highly thermally-conductive material), the liquid metal 104 also functions as a lubricant to minimize friction between the two bodies (as a liquid). The liquid metal 104 TIM between the heat-generating device 106 and the solid structure 102 is preferably very thin (e.g., less than 0.1 mm (millimeter)) and preferably has relatively high thermal conductivity (e.g., more than 10 W/mK (watts per meter per degree Kelvin)).

### Augmented Cooling

While the heat transferred from the heat-generating device 106 to the solid structure 102 is expected to naturally move and dissipate within the body of the solid structure 102 via conduction and without the body of the solid structure 102 via conduction and/or convection to the surrounding environment, one or more augmented cooling systems may be implemented in conjunction with a system such as cooling system 100. Any of the various known cooling techniques may be implemented to assist in cooling of the solid structure 102, such as circulating water cooling, direct air cooling with fins and fan(s), non-water (e.g., fluorocarbon) boiling liquid cooling, or a combination of any of the foregoing, for non-limiting examples.

FIG. 2 is a diagram illustrating an electronics cooling system with external heat dissipator, according to an embodiment. Augmented cooling system 200 (“cooling system 200”) is an example that may be implemented to assist in removing the transferred heat (from heat-generating device 106) from the solid structure 102. Cooling system 200 comprises an implementation of cooling system 100 (FIG. 1) in thermal communication with a heat-generating device 106, housed in an enclosure 205, and immersed in a chamber 208 filled with water 209 at low pressure. This example of a cooling system 100 comprises a spinning (revolving) copper disk 202 (“disk 202”) housed in the enclosure 205 along with a liquid metal 204, where the enclosure 205 is in thermally-conductive communication with the heat-generating device 106. Alternatively to a disk, a thicker solid structure (e.g., a drum) may be used for solid structure 102. Preferably, the enclosure 205 walls are very thin (e.g., less than 1 mm) and with relatively high thermal conductivity (e.g., more than 100 W/mK). Cooling system 200 further comprises a condenser 210 coupled with the chamber 208 and a corresponding cooling fan 212 external to the chamber 208.

In this context, heat is removed from the heat-generating device 106 (e.g., a high-power chip) to the environment in a continuous cycle as follows. As described generally in reference to cooling system 100 of FIG. 1, heat moves from the heat-generating device 106 to the spinning copper disk 202 through the enclosure 205 and the liquid metal 204. As such, the heat creates a “hot spot” on the disk 202 surface. The disk 202 is constantly rotating, thus the hot spot is quickly removed from the heat-emanating surface of heat-generating device 106. The hot-spot is cooled by the evaporation of the low-pressure water 209 outside of the disk 202 and enclosure 205. Evaporated water (or steam) goes into the condenser 210, over which cooling airflow is blown by the fan 212, and is condensed back to liquid water, which returns back into the chamber 208. By repeating these steps, the chip always receives cold copper surface that provides efficient heat conduction, e.g., “continuous transient cooling”.

### Solid-Convection Structure Examples

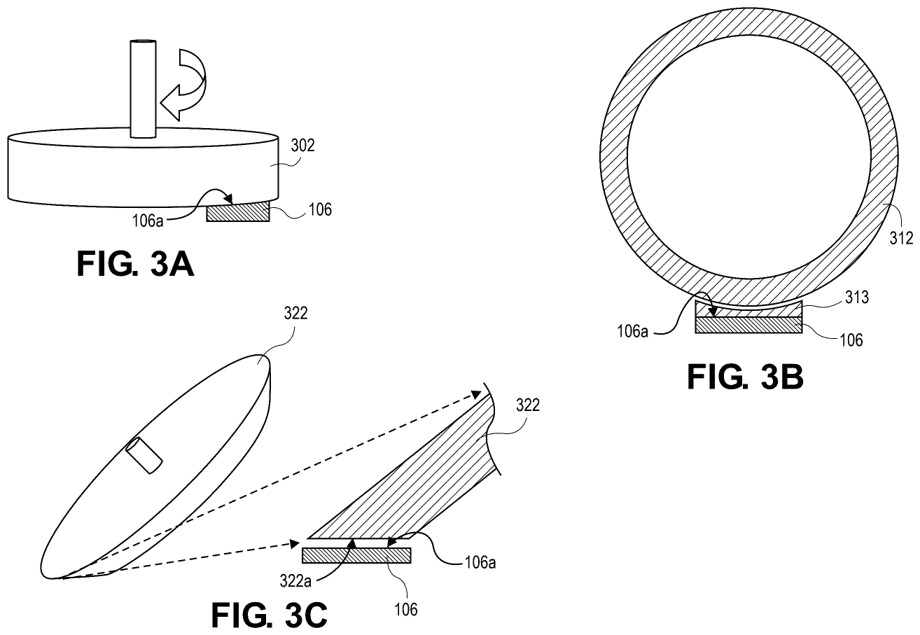

In addition to the high-thermal-conductivity material used, the shape, dimensions, orientation, etc. (generally “configuration”) of a solid structure 102 may also vary from implementation to implementation based on the design goals and constraints. FIGS. 3A-3C illustrate some non-limiting examples of configurations for a solid structure 102 for implementation in a cooling system 100 as illustrated and described in reference to FIG. 1.

FIG. 3A is a diagram illustrating a parallel solid conductive structure for an electronics cooling system, according to an embodiment. According to this embodiment, a solid structure 302 comprises a disk-shaped structure (“disk 302”) positioned in a plane substantially parallel to a primary heat-emanating surface 106a of the heat-generating device 106, and the disk 302 is configured to rotate, revolve, spin in the plane such that a portion of the disk 302 passes over the primary heat-emanating surface 106a of the heat-generating device 106 for the purposes described herein. Such a horizontal orientation is in contrast with the vertical orientation illustrated in reference to solid structure 202 of FIG. 2. Any conventional or known form of motor or driving mechanism may be utilized to revolve the disk 302 in the plane of the disk 302. According to an embodiment and as illustrated in FIG. 3A, the portion of disk 302 that passes over the primary heat-emanating surface 106a of the heat-generating device 106 is a radially outer portion of the disk.

FIG. 3B is a diagram illustrating a perpendicular solid conductive ring structure for an electronics cooling system, according to an embodiment. According to this embodiment, a solid structure 312 comprises an annular or ring-shaped structure (“ring 312”) positioned in a plane substantially normal (perpendicular) to the primary heat-emanating surface 106a of the heat-generating device 106, and the ring 312 is configured to rotate, revolve, spin in the plane such that an outer circumferential edge of the ring 312 passes over the primary heat-emanating surface 106a of the heat-generating device 106 for the purposes described herein. Such a vertical orientation is consistent with the vertical orientation illustrated in reference to solid structure 202 of FIG. 2. Here also, any conventional or known form of motor or driving mechanism may be utilized to revolve the ring 312 in the plane of the ring 312. According to an embodiment, an additional metal thermal bridge 313 having a concave surface may be positioned between the heat-emanating surface 106a of the heat-generating device 106 and the ring 312, to maintain a small gap between to facilitate the transfer of heat from the heat-generating device 106 to the similarly-curved outer rim of vertically-oriented ring 312. Such a thermal bridge 313 is not necessary for the disk 302 embodiment of FIG. 3A because the heat-receiving surface of the disk 302 is parallel to the heat-emanating surface 106a.

FIG. 3C is a diagram illustrating a solid conductive structure at an acute angle for an electronics cooling system, according to an embodiment. According to this embodiment, a solid structure 322 comprises canted disk-shaped structure (“canted disk 322”) positioned in a plane at an acute angle to the primary heat-emanating surface 106a of the heat-generating device 106, and the canted disk 322 is configured to rotate, revolve, spin in the plane such that an outer circumferential portion of the canted disk 322 passes over the primary heat-emanating surface 106a of the heat-generating device 106 for the purposes described herein. Such an angled, canted orientation may be preferred over a vertical orientation if there are vertical space constraints in the installation environment. Here also, any conventional or known form of motor or driving mechanism may be utilized to revolve the canted disk 322 in the plane of the canted disk 322. According to an embodiment, the outer circumferential portion/edge of the canted disk 322 comprises a chamfered surface 322a substantially parallel to the primary heat-emanating surface 106a of the heat-generating device 106.

### Translating Solid-Convection Structure

In addition to rotating, revolving, spinning the heat-absorbing solid structure such as solid structure 102 (FIG. 1), 202 (FIG. 2), 302 (FIG. 3A), 312 (FIG. 3B), 322 (FIG. 3C), the solid structure may be configured for translation over the heat-emanating surface 106a of the heat-generating device 106.

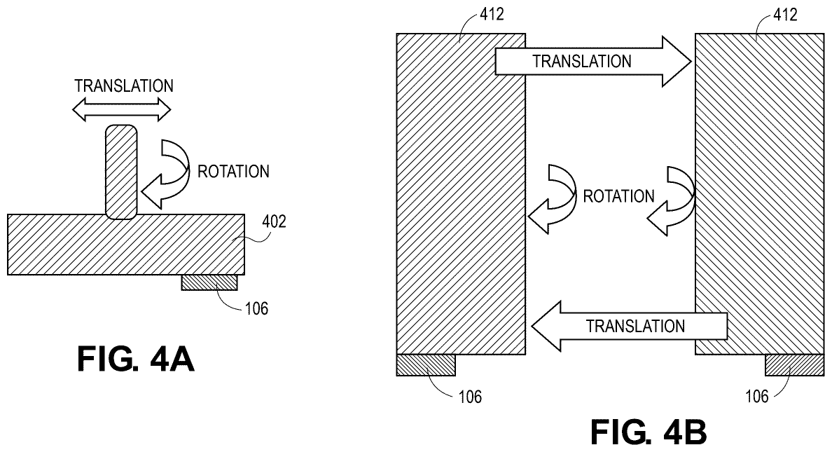

FIG. 4A is a diagram illustrating a parallel translating solid conductive structure for an electronics cooling system, according to an embodiment. According to an embodiment, after some certain time less than the time constant of the system (e.g., after one horizontal rotation of a solid structure 402, here “disk 402”), the disk 402 is translated (e.g., moved sideways) so that the heat-generating device 106 encounters “fresh” portion(s) of the high-thermal-conductivity solid disk 402. For example, the entire disk 402 enclosure (see, e.g., enclosure 205 of FIG. 2) may be translated over the heat-generating device 106, or the disk 402 may be moved within the corresponding enclosure. Thus, the heat-generating device 106 contacts the disk 402 at different radii from the center of rotation.

FIG. 4B is a diagram illustrating a perpendicular translating solid conductive structure for an electronics cooling system, according to an embodiment. According to an embodiment, after some certain time less than the time constant of the system (e.g., after one vertical rotation of a solid structure 412, here “disk 412”), the disk 412 is translated (e.g., moved sideways) so that the heat-generating device 106 encounters “fresh” portion(s) of the high-thermal-conductivity solid disk 412. For example, the entire disk 412 enclosure (see, e.g., enclosure 205 of FIG. 2) may be translated over the heat-generating device 106, or the disk 412 may be moved within the corresponding enclosure. Thus, the heat-generating device 106 contacts the disk 412 at different portions of the circumferential edge of the disk 412. With this embodiment, a thicker disk 412 (e.g., a drum or cylinder) may be employed, thus resulting in more rotations before translating back to a prior position over the heat-generating device 106.

### Augmenting Cooling System Examples

As illustrated and described in reference to FIG. 2, an external cooling system (see, e.g., augmented cooling system 200) may be implemented with an augmenting cooling system to assist in removing the transferred heat (from heat-generating device 106) from the corresponding solid structure 102 (FIG. 1), 202 (FIG. 2), 302 (FIG. 3A), 312 (FIG. 3B), 322 (FIG. 3C), 402 (FIG. 4A), 412 (FIG. 4B).

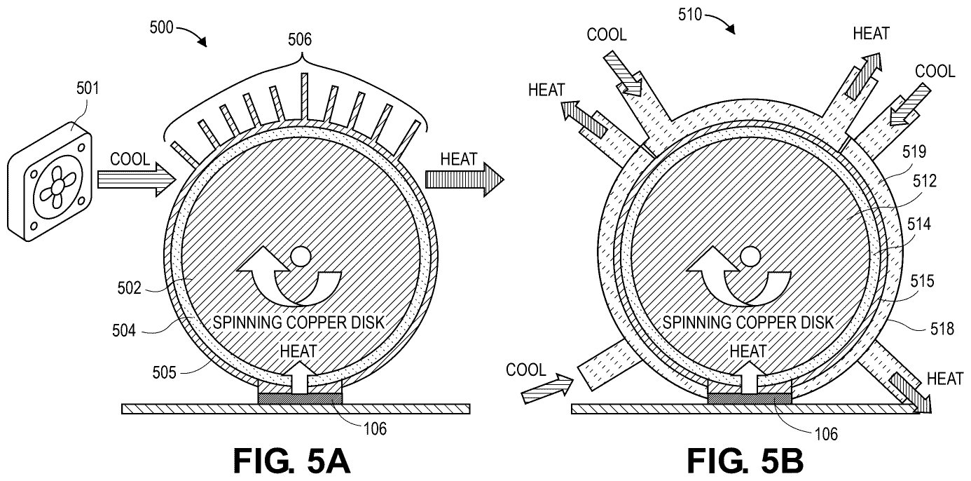

FIG. 5A is a diagram illustrating a perpendicular solid conductive structure with heat-conducting appendages for an air-cooled electronics cooling system, according to an embodiment. Air-cooled cooling system 500 comprises an implementation of cooling system 100 (FIG. 1) in thermal communication with a heat-generating device 106. This example of a cooling system 500 comprises a spinning (revolving) copper disk 502 (“disk 502”) housed in an enclosure 505 along with a liquid metal 504, where the enclosure 505 is in thermally-conductive communication with the heat-generating device 106. In the embodiment illustrated, enclosure 505 further comprises a set of heat-conducting appendages 506 (e.g., “fins”) coupled with the enclosure 505. Here, a corresponding cooling fan 501 external to the enclosure 505 is utilized to blow cool air over the appendages 506. Additionally, or alternatively, heat-conducting appendages may be implemented directly onto the outer perimeter of the disk 502 and/or on the inside of enclosure 505, to increase the surface area of heat exchange at hot location(s) of disk 502.

FIG. 5B is a diagram illustrating a perpendicular solid conductive structure for a liquid-cooled electronics cooling system, according to an embodiment. Liquid-cooled cooling system 510 comprises an implementation of cooling system 100 (FIG. 1) in thermal communication with a heat-generating device 106. This example of a cooling system 510 comprises a spinning (revolving) copper disk 512 (“disk 512”) housed in an enclosure 515 along with a liquid metal 514, where the enclosure 515 is in thermally-conductive communication with the heat-generating device 106. In the embodiment illustrated, the enclosure 515 (and the corresponding internal components) is immersed in a chamber 518 filled with a cooling liquid 519 (water, liquid metal, fluorocarbon, etc.). Shown here are multiple entry and exit points for the cooling liquid 519, for purposes of more efficient cooling. However, a single entry and exit point may be implemented.

### Liquid Metal as Fluid Dynamic Bearing

As described in reference to FIG. 1, the liquid metal 104 (TIM) between the heat-generating device 106 and the solid structure 102 is preferably very thin (e.g., less than 0.1 mm). Thus, according to an embodiment, a fluid dynamic bearing is employed on the interface surface to precisely maintain a small gap between the heat-generating device 106 and the solid structure 102. A fluid dynamic bearing (FDB), also referred to as a hydrodynamic bearing, is a type of non-contact bearing in which the load is supported by a thin layer of rapidly moving liquid (or gas) between the bearing surfaces.

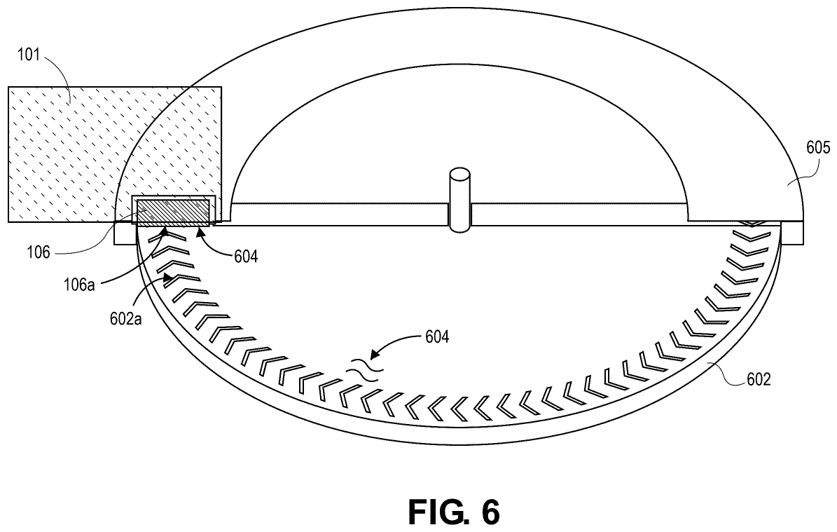

FIG. 6 is a diagram illustrating a parallel solid conductive structure configured for a fluid dynamic bearing for an electronics cooling system, according to an embodiment. To precisely maintain a small gap between the heat-generating device 106 and the solid structure 602, the solid structure 602 (e.g., “disk 602”) comprises a series of etchings 602a (or protrusions) around the portion of the disk 602, where the series of etchings 602a is configured to move the liquid metal 604 in such a way so that the liquid metal 604 functions as a FDB between the rotating disk 602 and a heat-generating device 106 (e.g., a chip) of an electronic device 101.

### Method for Removing Heat From a Heat-Generating Device

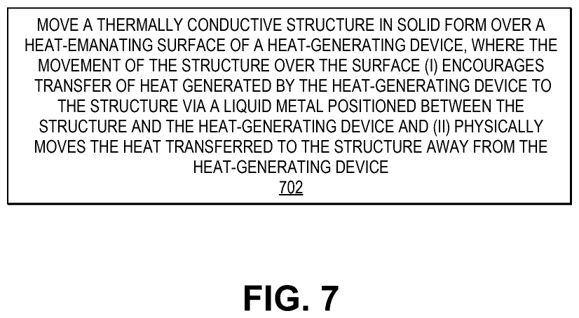

FIG. 7 is a flow diagram illustrating a method for removing heat from a heat-generating device, according to an embodiment. The method of FIG. 7 characterizes a method for removing heat by way of a cooling system such as cooling system 100 of FIG. 1.

At block 702, move a thermally conductive structure in solid form over a heat-emanating surface of a heat-generating device, where the movement of the structure over the heat-emanating surface of the heat-generating device (i) encourages transfer of heat generated by the heat-generating device to the structure via a liquid metal positioned between the structure and the heat-generating device and (ii) physically moves the heat transferred to the structure away from the heat-generating device. For example, moving solid structure 102 (FIG. 1), 202 (FIG. 2), 302 (FIG. 3A), 312 (FIG. 3B), 322 (FIG. 3C), 402 (FIG. 4A), 412 (FIG. 4B), 502 (FIG. 5A), 512 (FIG. 5B) over a heat-emanating surface 106a of a heat-generating device 106, whereby the movement of the structure 102, 202, 302, 312, 322, 402, 412, 502, 512 over the heat-emanating surface 106a of the heat-generating device 106 (i) encourages transfer of heat generated by the heat-generating device 106 to the structure 102 et seq. via a liquid metal 104 (FIG. 1), 204 (FIG. 2), 504 (FIG. 5A), 514 (FIG. 5B), 604 (FIG. 6) positioned between the structure 102 et seq. and the heat-generating device 106 and (ii) physically moves the heat transferred to the structure 102 et seq. away from the heat-generating device 106.

As described elsewhere herein, according to an embodiment, moving the thermally conductive structure (block 702) may include rotating a disk structure positioned in a plane substantially parallel to the heat-emanating surface 106a of the heat-generating device 106 (see, e.g., solid structure 102 (FIG. 1), 302 (FIG. 3A), 402 (FIG. 4A), 602 (FIG. 6)) such that a portion of the disk structure passes over the heat-emanating surface 106a of the heat-generating device 106. As described elsewhere herein, according to an embodiment, moving the thermally conductive structure (block 702) may include rotating a disk structure positioned in a plane at an angle to the heat-emanating surface 106a of the heat-generating device 106 (see, e.g., solid structure 102 (FIG. 1), 202 (FIG. 2), 312 (FIG. 3B), 322 (FIG. 3C), 412 (FIG. 4B), 502 (FIG. 5A), 512 (FIG. 5B)), such that an outer circumferential edge of the disk passes over the heat-emanating surface 106a of the heat-generating device 106. Furthermore, and as described elsewhere herein, according to an embodiment, moving the thermally conductive structure (block 702) may include translating the structure back and forth over the surface of the heat-generating device (see, e.g., solid structure 402 (FIG. 4A), 422 (FIG. 4B)).

In view of the foregoing, described herein are approaches to cooling semiconductor chips, especially useful in the context of cooling ultra-high heat flux devices such as some CPUs and GPUs. Because the high-thermal-conductivity solid structure is continuously moving, a continuous cycle of heat transfer, physical movement, and dissipation for cooling the heat-generating device is provided.

### Extensions and Alternatives

In the foregoing description, embodiments of the invention have been described with reference to numerous specific details that may vary from implementation to implementation. Therefore, various modifications and changes may be made thereto without departing from the broader spirit and scope of the embodiments. Thus, the sole and exclusive indicator of what is the invention, and is intended by the applicant(s) to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage, or attribute that is not expressly recited in a claim should limit the scope of such claim in any way. The specification and drawings are, accordingly, to be regarded in an illustrative rather than a restrictive sense.

In addition, in this description certain process steps may be set forth in a particular order, and alphabetic and alphanumeric labels may be used to identify certain steps. Unless specifically stated in the description, embodiments are not necessarily limited to any particular order of carrying out such steps. In particular, the labels are used merely for convenient identification of steps and are not intended to specify or require a particular order of carrying out such steps.

What is claimed is:

1. A system comprising:
a thermally conductive structure in solid form configured for moving over a surface of a heat-generating device; and
a liquid metal positioned between the structure and the heat-generating device;
wherein movement of the structure over the surface of the heat-generating device facilitates transfer of heat generated by the heat-generating device to the structure via the liquid metal and physically moves the heat transferred to the structure away from the heat-generating device.

2. The system of claim 1, wherein:
the structure comprises a disk positioned in a plane substantially parallel to a primary heat-emanating surface of the heat-generating device; and
the disk is configured to rotate in the plane such that a portion of the disk passes over the primary heat-emanating surface of the heat-generating device.

3. The system of claim 2, wherein the portion of the disk that passes over the primary heat-emanating surface of the heat-generating device is a radially outer portion of the disk.

4. The system of claim 2, wherein:
the structure comprises a series of etchings or protrusions around the portion of the disk; and
the series is configured such that the liquid metal functions as a fluid dynamic bearing for the rotating disk.

5. The system of claim 1, wherein:
the structure comprises a disk positioned in a plane at an angle to a primary heat-emanating surface of the heat-generating device; and
the disk is configured to rotate in the plane such that an outer circumferential edge of the disk passes over the primary heat-emanating surface of the heat-generating device.

6. The system of claim 5, wherein:
the disk is annular in form.

7. The system of claim 5, wherein:
the disk is positioned at an acute angle to the primary heat-emanating surface of the heat-generating device; and
the outer circumferential edge of the disk comprises a chamfered surface substantially parallel to the primary heat-emanating surface of the heat-generating device.

8. The system of claim 1, further comprising:
an enclosure in which the structure and the liquid metal are enclosed; and
means, external to the enclosure, for dissipating the heat transferred to the structure.

9. The system of claim 8, further comprising:
one or more heat-conducting appendages coupled with the enclosure.

10. The system of claim 1, wherein the structure is configured for translational movement back and forth over a primary heat-emanating surface of the heat-generating device.

11. The system of claim 10, wherein the structure comprises a metal material in the form of tape.

12. The system of claim 1, wherein the structure comprises copper.

13. The system of claim 1, wherein the liquid metal comprises InGaSn (Indium-Gallium-Tin).

14. A method for removing heat from a heat-generating device, the method comprising:
moving a thermally conductive structure in solid form over a heat-emanating surface of a heat-generating device; and
wherein the movement of the structure over the heat-emanating surface of the heat-generating device (i) encourages transfer of heat generated by the heat-generating device to the structure via a liquid metal positioned between the structure and the heat-generating device and (ii) physically moves the heat transferred to the structure away from the heat-generating device.

15. The method of claim 14, wherein moving the thermally conductive structure includes rotating a disk structure positioned in a plane substantially parallel to the heat-emanating surface of the heat-generating device, such that a portion of the disk structure passes over the heat-emanating surface of the heat-generating device.

16. The method of claim 14, wherein moving the thermally conductive structure includes rotating a disk structure positioned in a plane at an angle to the heat-emanating surface of the heat-generating device, such that an outer circumferential edge of the disk structure passes over the heat-emanating surface of the heat-generating device.

17. The method of claim 16, wherein rotating the disk structure includes rotating the disk structure positioned at an acute angle to the heat-emanating surface of the heat-generating device, the disk structure comprising a chamfered surface substantially parallel to the heat-emanating surface of the heat-generating device.

18. The method of claim 14, further comprising:
further dissipating the heat transferred to the structure, through an enclosure in which the structure and the liquid metal are enclosed, by means external to the enclosure.

19. The method of claim 14, wherein moving the thermally conductive structure includes translating the structure back and forth over the surface of the heat-generating device.

20. An electronics cooling system comprising:
a solid copper structure configured for moving over a heat-emanating surface of a heat-generating chip comprising one or more electronic circuits;
a liquid metal positioned between the copper structure and the heat-generating chip;
an enclosure housing the copper structure and the liquid metal; and
means, external to the enclosure, for dissipating the heat transferred to the copper structure from the heat-generating chip;
wherein movement of the copper structure over the heat-emanating surface of the heat-generating chip promotes transfer of heat generated by the heat-generating chip to the copper structure via the liquid metal and physically moves the heat transferred to the copper structure away from the heat-generating chip for further removal from within the enclosure by the means for dissipating.
